(19) United States
(12) Patent Application Publication
(10) Pub. No.: US 2025/0354006 A1
(43) Pub. Date: Nov. 20, 2025

(54) RESIN COMPOSITION AND ARTICLE MANUFACTURED USING THE SAME

(71) Applicant: Elite Material Co., Ltd., Taoyuan City (TW)

(72) Inventor: Shu-Hao CHANG, Taoyuan City (TW)

(21) Appl. No.: 18/814,766

(22) Filed: Aug. 26, 2024

(30) Foreign Application Priority Data
May 16, 2024 (TW) 113118148

(51) Int. Cl. C08L 65/02; C08J 5/24

(52) U.S. Cl. CPC C08L 65/02; C08J 5/244; C08J 2365/02; C08L 2205/03

(57) ABSTRACT

A resin composition includes 100 parts by weight of vinyl-containing polyphenylene ether resin; 8 parts by weight to 20 parts by weight of a compound represented by the following formula (1); and 0.5 parts by weight to 2.5 parts by weight of a compound represented by the following formula (2),

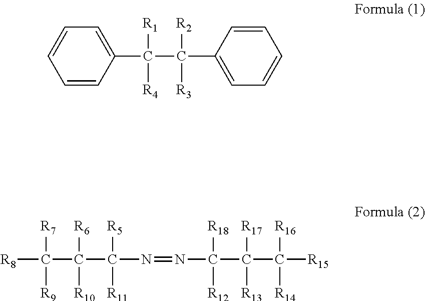

wherein each R₁, R₂, R₃ and R₄ respectively is C₁₋₄ alkyl or H, and each R₅, R₆, R₇, R₈, R₉, R₁₀, R₁₁, R₁₂, R₁₃, R₁₄, R₁₅, R₁₆, R₁₇ and R₁₈ respectively is C₁ alkyl or H. An article manufactured using the aforesaid resin composition is also provided.

### CROSS-REFERENCE TO RELATED APPLICATIONS

This application claims the benefits of the Taiwan Patent Application Serial Number 113118148, filed on May 16, 2024, the subject matter of which is incorporated herein by reference.

### BACKGROUND OF THE INVENTION

### Field

The present invention provides a resin composition and an article manufactured using the same. More specifically, the present invention provides a resin composition with improved properties and an article manufactured using the same.

### Description of Related Art

The operation of electronic equipment is achieved by connecting numerous electronic components through conductive lines on the circuit board for power supply and signal transmission. A circuit board (such as a printed circuit board) is generally composed of an insulating substrate and a conductive circuit pattern located on the insulating substrate, and the laminate is one of the key raw materials for making the circuit board.

With the rapid development of the fifth-generation mobile communication technology (5G) and the high functionality and miniaturization of the electronic equipment, the circuit boards used are also developing in the direction of multi-layering, high-density wiring and high-speed signal transmission. In addition, in order to ensure the quality of electronic equipment, there are also higher requirements for the overall performance of laminates. The resin composition is the basic raw material for preparing laminates. The design of the resin composition directly affects the performance of laminates and circuit substrates.

Therefore, how to develop a resin composition suitable for high-performance circuit boards is the current direction of the industry's active efforts.

### SUMMARY OF THE INVENTION

In view of the problems encountered in the prior art, especially the inability of existing resin compositions to meet one or more of the above performance requirements, the main object of the present invention is to provide a resin composition and an article thereof that can meet the above performance requirements.

The present invention provides a resin composition, comprising: 100 parts by weight of vinyl-containing polyphenylene ether resin; 8 parts by weight to 20 parts by weight of a compound represented by the following formula (1); and 0.5 parts by weight to 2.5 parts by weight of a compound represented by the following formula (2),

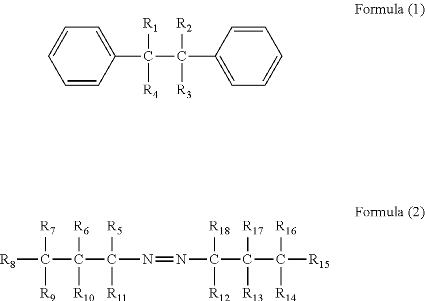

wherein each R₁, R₂, R₃ and R₄ respectively is C₁₋₄ alkyl or H, and each R₅, R₆, R₇, R₈, R₉, R₁₀, R₁₁, R₁₂, R₁₃, R₁₄, R₁₅, R₁₆, R₁₇ and R₁₈ respectively is C₁ alkyl or H.

The present invention also provides an article manufactured using the aforesaid resin composition, wherein the article includes a prepreg, a resin film, a laminate or a printed circuit board.

The article manufactured using the resin composition of the present invention, such as a prepreg, a resin film, a laminate or a printed circuit board, has excellent characteristics in at least one of the copper foil peel strength of the copper-containing laminate, the interlayer bonding strength of the copper-containing laminate and the percentage of thermal expansion at Z-axis, and therefore can be used as a high-performance laminate that meet comprehensive needs.

### BRIEF DESCRIPTION OF DRAWINGS

FIG. 1 is a schematic diagram showing a dried board appearance of a copper-free laminate.

FIG. 2 is a schematic diagram showing a normal appearance of a copper-free laminate.

### DETAILED DESCRIPTION OF THE INVENTION

The following examples are only used to illustrate the embodiments of the present invention and are not intended to limit the present invention.

The terms used herein have the same meaning as those generally understood by the skilled person in the art. If otherwise specified herein, the terms defined herein shall prevail.

In the present specification, the terms “comprise”, “include”, “have”, “contain” or any other similar terms are open-ended transitional phrases. The terms “consisting of” and “consist” are closed-transitional phrases.

In the present specification, the term “a composition comprises A, B and C, wherein A comprises a1, a2 or a3” has the same meaning as the term “a composition comprises A, B and C, wherein A comprises a1, a2, a3 or a combination thereof”, that is “a composition comprises A, B and C, where A comprises a1, a2, a3, the combination of a1 and a2, the combination of a1 and a3, the combination of a2 and a3 or the combination of a1, a2 and a3.”

Numerical ranges used herein include all possible subranges, and all individual numerical values (including decimals and integers) within the stated range.

Numerical values used herein include all numerical ranges that are equal to the numerical values after rounding to the number of significant digits in the numerical values.

The polymer used herein includes homopolymers, copolymers, prepolymers, etc., but the present invention is not limited thereto. The polymer also includes oligomers.

In the present specification, the “copolymer” refers to the product formed by polymerization reaction of two or more kinds of monomers, and includes but not limited to random copolymers, alternating copolymers, graft copolymers or block copolymers. For example, a styrene-butadiene copolymer is a product obtained by polymerization of only two kinds of monomers of styrene and butadiene. For example, styrene-butadiene copolymers include, but are not limited to styrene-butadiene random copolymers, styrene-butadiene alternating copolymers, styrene-butadiene graft copolymers or styrene-butadiene block copolymers. Styrene-butadiene block copolymers include, but are not limited to, the polymerized molecular structure of styrene-styrene-styrene-butadiene-butadiene-butadiene-butadiene. Styrene-butadiene block copolymers include, for example, but are not limited to, styrene-butadiene-styrene block copolymers. Styrene-butadiene-styrene block copolymers include, for example, but are not limited to, the polymerized molecular structure of styrene-styrene-styrene-butadiene-butadiene-butadiene-butadiene-styrene-styrene-styrene. Similarly, hydrogenated styrene-butadiene copolymers include hydrogenated styrene-butadiene random copolymers, hydrogenated styrene-butadiene alternating copolymers, hydrogenated styrene-butadiene graft copolymers or hydrogenated styrene-butadiene block copolymer. Hydrogenated styrene-butadiene block copolymers include, for example but are not limited to, hydrogenated styrene-butadiene-styrene block copolymers.

In the present invention, “resin” may include, but is not limited to monomers, polymers formed by monomers, combinations of monomers, combinations of polymers formed by monomers or combinations of monomers and polymers formed by monomers when interpretation. For example, in the present invention, “maleimide resin” includes maleimide monomers, maleimide polymers formed by maleimide monomers, combinations of maleimide monomers, combinations of maleimide polymers formed by maleimide monomers or combinations of maleimide monomers and maleimide polymers formed by maleimide monomers.

In the present specification, “vinyl group-containing” may include vinyl group, vinylene group, allyl group, (meth)acrylate group or vinylbenzyl group.

In the present invention, a modification includes: the product that the reaction functional group of the resin is modified, the product formed by the prepolymerization reaction of the resin and other resin, the product formed by the cross-linking between the resin and other resin, homopolymerized products of the resin, copolymerized products of the resin with other resins, etc. For example, the modification may be to replace the original terminal hydroxyl group with a terminal vinyl group through a chemical reaction, or to obtain a terminal hydroxyl group through a chemical reaction between the original terminal vinyl group and p-aminophenol.

In the present specification, the “unsaturated bond” described in the present invention refers to the reactive unsaturated bond, such as but not limited to the unsaturated double bond that can cross-link with other functional groups, such as but not limited to the unsaturated carbon-carbon double bond that can cross-link with other functional groups.

In the present specification, when specific examples of compounds are written in the form of “(substituent)”, they should be understood to include both cases with this substituent and cases without this substituent. For example, cyclohexanedimethanol di(meth)acrylate should be interpreted as including cyclohexanedimethanol diacrylate and cyclohexanedimethanol dimethacrylate; and (meth)acrylate should be interpreted as including acrylate and methacrylate.

In the present specification, part(s) by weight represents weight part(s), which can be any weight unit, such as but not limited to kilogram(s), gram(s), pound(s) and other weight units. For example, 100 parts by weight of maleimide resin means that it can be 100 kg of maleimide resin or 100 lbs of maleimide resin. If the resin solution includes solvent and resin, the parts by weight of the (solid or liquid) resin generally refers to the weight unit of the (solid or liquid) resin, and does not include the weight unit of the solvent in the solution. The parts by weight of the solvent refer to the weight unit of the solvent.

One embodiment of the present invention provides a resin composition, comprising: 100 parts by weight of vinyl-containing polyphenylene ether resin; 8 parts by weight to 20 parts by weight of a compound represented by the following formula (1); and 0.5 parts by weight to 2.5 parts by weight of a compound represented by the following formula (2).

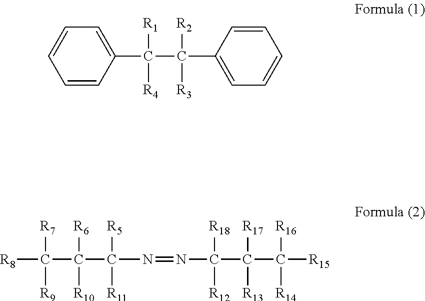

Wherein each R₁, R₂, R₃ and R₄ respectively is C₁₋₄ alkyl or H, and each R₅, R₆, R₇, R₈, R₉, R₁₀, R₁₁, R₁₂, R₁₃, R₁₄, R₁₅, R₁₆, R₁₇ and R₁₈ respectively is C₁ alkyl or H.

In one embodiment, the content of the vinyl-containing polyphenylene ether resin is 100 parts by weight, and the contents of other resins or additives are the relative contents related to 100 parts by weight of the vinyl-containing polyphenylene ether resin. For example, in one embodiment of the present invention, the content of the compound represented by the formula (1) may be 8 parts by weight to 20 parts by weight relative to 100 parts by weight of the vinyl-containing polyphenylene ether resin. For example, in one embodiment of the present invention, the resin composition may comprise 100 kg of the vinyl-containing polyphenylene ether resin, and 8 kg to 20 kg of the compound represented by the formula (1). For example, in one embodiment of the present invention, the resin composition may comprise 100 pounds of the vinyl-containing polyphenylene ether resin, and 8 pounds to 20 pounds of the compound represented by the formula (1).

In one embodiment, the content of the vinyl-containing polyphenylene ether resin is 100 parts by weight, and the contents of other resins or additives are the relative contents related to 100 parts by weight of the vinyl-containing polyphenylene ether resin. For example, in one embodiment of the present invention, the content of the compound represented by the formula (2) may be 0.5 parts by weight to 2.5 parts by weight relative to 100 parts by weight of the vinyl-containing polyphenylene ether resin. For example, in one embodiment of the present invention, the resin composition may comprise 100 kg of the vinyl-containing polyphenylene ether resin, and 0.5 kg to 2.5 kg of the compound represented by the formula (2). For example, in one embodiment of the present invention, the resin composition may comprise 100 pounds of the vinyl-containing polyphenylene ether resin, and 0.5 pounds to 2.5 pounds of the compound represented by the formula (2).

In one embodiment, the vinyl-containing polyphenylene ether resin may include various polyphenylene ether resins with terminals modified by vinyl, allyl or vinylene. The vinyl-containing polyphenylene ether resin may comprise but is not limited to: vinylbenzyl group-containing polyphenylene ether resin, (meth)acrylate-containing polyphenylene ether resin, vinylbenzyl group-containing bisphenol A polyphenylene ether resin or maleimide-containing polyphenylene ether resin. The vinyl-containing polyphenylene ether resins with terminals modified by vinyl, allyl or vinylene may be polymerized through the unsaturated bonds.

In one embodiment, the vinyl-containing polyphenylene ether resin may comprise various vinyl-containing polyphenylene ether resins known in the art. The vinyl-containing polyphenylene ether resin suitable for the present invention is not particularly limited and can be any one or more commercially available products or homemade products. In some embodiments, any one or more of the following vinyl-containing polyphenylene ether resins may be used: vinylbenzyl biphenyl-containing polyphenylene ether resin (such as OPE-2st, available from Mitsubishi Gas Chemical Co., Ltd.), methacrylate-containing polyphenylene ether resin (such as SA9000, available from Sabic Company) or vinylbenzyl group-containing bisphenol A polyphenylene ether resin. However, the present invention is not limited thereto.

In one embodiment, in the compound represented by the formula (1), each R₁, R₂, R₃ and R₄ may respectively be methyl, ethyl, isobutyl or hydrogen. In the compound represented by the formula (1), the polymerization reaction is initiated by free radicals generated through the breakage of the carbon-carbon bond between two carbon atoms respectively connected to the benzene ring in the structural formula. For example, the compound represented by the formula (1) may be a compound of the following formula (1-1), (1-2) or (1-3). For example, the compound represented by the formula (1) may be 2,3-dimethyl-2,3-diphenylbutane, 3,4-dimethyl-3,4-diphenylhexane or 2,7-dimethyl-4,5-diethyl-4,5-diphenyloctane.

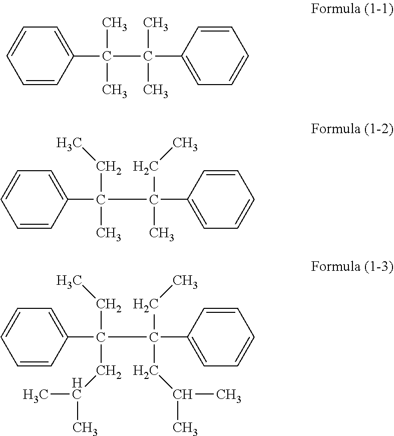

In one embodiment, in the compound represented by the formula (2), each R₅, R₆, R₇, R₈, R₉, R₁₀, R₁₁, R₁₂, R₁₃, R₁₄, R₁₅, R₁₆, R₁₇ or R₁₈ respectively is C₁ alkyl or H. For example, the compound represented by the formula (2) may comprise a compound of the following formula (2-1) or a compound of the following formula (2-2).

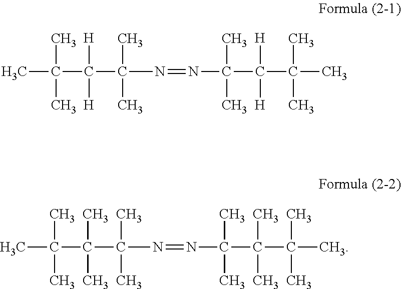

In one embodiment, the resin composition may further comprise: divinylbenzene copolymer, maleimide resin, polyolefin other than divinylbenzene copolymer, di(vinylphenyl)ethane, triallyl isocyanurate, triallyl cyanurate, divinylbenzene, diallyl isophthalate, styrene maleic anhydride copolymer resin, phenol resin, benzoxazine resin, cyanate ester resin, polysiloxane resin, polyester resin, epoxy resin, polyamide resin, polyimide resin or a combination of thereof.

In one embodiment, with respect to 100 parts by weight of the vinyl-containing polyphenylene ether resin, the resin composition may further comprise 8 parts by weight to 30 parts by weight of divinylbenzene copolymer, but the present invention is not limited thereto. The divinylbenzene copolymer may comprise divinylbenzene-ethylstyrene-styrene terpolymer, styrene-butadiene-divinylbenzene terpolymer or a combination thereof.

In one embodiment, the resin composition may further comprise a maleimide resin, and the content of the maleimide resin is not particularly limited. In another embodiment with respect to 100 parts by weight of the vinyl-containing polyphenylene ether resin, the resin composition may further comprise 10 parts by weight to 45 parts by weight of the maleimide resin, but the present invention is not limited thereto. In further another embodiment, the resin composition may not comprise the maleimide resin, and at this time the content of the maleimide resin is 0 parts by weight; here, it means that the maleimide resin is not intentionally added into the resin composition. In further another embodiment, when the resin composition comprises the maleimide resin, the total content of the maleimide resin may be 10 parts by weight to 45 parts by weight or 10 parts by weight to 42 parts by weight. However, the present invention is not limited thereto, and the content of the maleimide resin may be adjusted according to the needs.

In one embodiment, the maleimide resin may comprise 4,4′-diphenylmethane bismaleimide, polyphenylmethane maleimide (or called as oligomer of phenylmethane maleimide), bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl) hexane, N-2,3-xylylmaleimide, N-2,6-xylylmaleimide, N-phenylmaleimide, vinyl benzyl maleimide, maleimide with biphenyl structure, maleimide resin containing C₁₀₋₅₀ aliphatic long chain structure, prepolymer of diallyl compound and maleimide resin, prepolymer of multifunctional amine and maleimide resin (herein, the multifunctional amine includes two or more amine groups), prepolymer of aminophenol and maleimide resin, or a combination thereof.

For example, specific examples of maleimide resin include, but are not limited to, maleimide resin produced by Daiwakasei Industry Co., Ltd. with trade names BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 or BMI-7000H, maleimide resin produced by K.I Chemical Co., Ltd. with trade names BMI-70 or BMI-80, or maleimide resin produced by Nippon Kayaku Co., Ltd. with trade names MIR-3000 or MIR-5000.

For example, specific examples of maleimide resin containing C₁₀₋₅₀ aliphatic long chain structure include, but are not limited to, maleimide resin containing C₁₀₋₅₀ aliphatic long chain structure produced by Designer Molecular Co., Ltd. with trade names BMI-689, BMI-1400, BMI-1500, BMI-1700, BMI-2500, BMI-3000, BMI-5000 or BMI-6000, or maleimide resin containing C₁₀₋₅₀ aliphatic long chain structure produced by Shin-etsu chemical co., Ltd. with trade names SLK-3000 series, SLK-1500 series or SLK-2000 series. The structure of SLK-3000 produced by Shin-etsu chemical co., Ltd. is the same as the structure of BMI-3000 produced by Designer Molecular Co., Ltd.

In one embodiment, with respect to 100 parts by weight of the vinyl-containing polyphenylene ether resin, the resin composition may further comprise 5 parts by weight to 30 parts by weight of polyolefin other than divinylbenzene copolymer, but the present invention is not limited thereto. In another embodiment, when the resin composition comprises the polyolefin other than divinylbenzene copolymer, the content of the polyolefin other than divinylbenzene copolymer may be 5 parts by weight to 30 parts by weight or 8 parts by weight to 30 parts by weight. However, the present invention is not limited thereto, and the content of the polyolefin other than the divinylbenzene copolymer may be adjusted according to the needs. Furthermore, the aforesaid polyolefin other than divinylbenzene copolymer may comprise vinyl-containing polyolefin other than the divinylbenzene copolymer, hydrogenated polyolefin or a combination thereof.

In one embodiment, the resin composition may further comprise vinyl-containing polyolefin other than the divinylbenzene copolymer, and the content of the vinyl-containing polyolefin other than the divinylbenzene copolymer is not particularly limited. In another embodiment, with respect to 100 parts by weight of the vinyl-containing polyphenylene ether resin, the resin composition may further comprise 5 parts by weight to 10 parts by weight of the vinyl-containing polyolefin other than the divinylbenzene copolymer, but the present invention is not limited thereto. In further another embodiment, the resin composition may not comprise the vinyl-containing polyolefin other than the divinylbenzene copolymer, and at this time the content of the vinyl-containing polyolefin other than the divinylbenzene copolymer is 0 parts by weight; here, it means that the vinyl-containing polyolefin other than the divinylbenzene copolymer is not intentionally added into the resin composition. The type of the vinyl-containing polyolefin other than the divinylbenzene copolymer are not particularly limited, and may comprise various vinyl-containing olefin polymers other than divinylbenzene copolymer known in the art, which may comprise, for example, but not limited to, polybutadiene, polyisoprene, styrene-butadiene copolymer, styrene-isoprene copolymer, butadiene-styrene copolymer adducted with maleic anhydride, vinyl-polybutadiene-urea ester oligomer, polybutadiene adducted with maleic anhydride or a combination thereof.

In one embodiment, the resin composition may further comprise hydrogenated polyolefin, and the content of the hydrogenated polyolefin is not particularly limited. In another embodiment, with respect to 100 parts by weight of the vinyl-containing polyphenylene ether resin, the resin composition may further comprise 5 parts by weight to 30 parts by weight of the hydrogenated polyolefin, but the present invention is not limited thereto, In further another embodiment, the resin composition may not comprise the hydrogenated polyolefin, and at this time the content of the hydrogenated polyolefin is 0 parts by weight; here, it means that the hydrogenated polyolefin is not intentionally added into the resin composition. The types of the aforesaid hydrogenated polyolefin are not particularly limited, and may comprise various hydrogenated styrene-butadiene-styrene block copolymers (also called as styrene-ethylene/butylene-styrene copolymer) known in the art. The hydrogenated polyolefin suitable for use in the present invention may be any one or more commercially available products or homemade products. For example, the hydrogenated polyolefin may comprise, but is not limited to hydrogenated styrene-butadiene-styrene block copolymer or hydrogenated styrene-butadiene-styrene block copolymer substituted with maleic anhydride. That is, the hydrogenated polyolefin may comprise, but is not limited to unsubstituted hydrogenated styrene-butadiene-styrene triblock copolymer, hydrogenated styrene-butadiene-styrene triblock copolymers substituted with maleic anhydride or a combination thereof. For example, the hydrogenated polyolefin may comprise, but is not limited to hydrogenated polyolefin produced by Asahi KASEI Corporation with the trade names H1221, H1062, H1521, H1052, H1041, H1053, H1051, H1517, H1043, N504, H1272, M1943, M1911 or M1913, hydrogenated polyolefin produced by KRATON company with trade names G1650, G1651, G1652, G1654, G1657, G1726, FG1901 or FG1924, or hydrogenated polyolefin produced by Kuraray Company with trade names 8004, 8006 or 8007L.

In one embodiment, the resin composition may further comprise di(vinylphenyl)ethane, and the content of the di(vinylphenyl)ethane is not particularly limited. In another embodiment, with respect to 100 parts by weight of the vinyl-containing polyphenylene ether resin, the resin composition may further comprise 5 parts by weight to 20 parts by weight of the di(vinylphenyl)ethane, but the present invention is not limited thereto. In further another embodiment, the resin composition may not comprise the di(vinylphenyl)ethane, and at this time the content of the di(vinylphenyl)ethane is 0 parts by weight; here, it means that the di(vinylphenyl)ethane is not intentionally added into the resin composition. In one embodiment, when the resin composition comprises the di(vinylphenyl)ethane, the content of the di(vinylphenyl)ethane may be 5 parts by weight to 20 parts by weight or 10 parts by weight to 17 parts by weight. However, the present invention is not limited thereto, and the content of the di(vinylphenyl)ethane may be adjusted according to the needs.

In one embodiment, the resin composition may further comprise triallyl isocyanurate. In another embodiment, the resin composition may not comprise the triallyl isocyanurate, and that is the content of the triallyl isocyanurate is 0 parts by weight; here, it means that the triallyl isocyanurate is not intentionally added into the resin composition. In further another embodiment, when the resin composition comprises the triallyl isocyanurate, the content of the triallyl isocyanurate may be 1 part by weight to 10 parts by weight or 3 parts by weight to 5 parts by weight. However, the present invention is not limited thereto, and the content of the triallyl isocyanurate may be adjusted according to the needs.

In one embodiment, in the styrene maleic anhydride copolymer resin (referred to as styrene maleic anhydride resin), the ratio of styrene to maleic anhydride may be 1:1, 2:1, 3:1, 4:1, 6:1 or 8:1. Specific examples of the styrene maleic anhydride copolymer resin may comprise but are not limited to, styrene maleic anhydride copolymer available from Cray Valley with trade names SMA-1000, SMA-2000, SMA-3000, EF-30, EF-40, EF-60 or EF-80, or styrene maleic anhydride copolymer available from Polyscope with trade names C400, C500, C700 or C900. The styrene maleic anhydride resin may also be esterified styrene maleic anhydride copolymer, which may be, for example, the esterified styrene maleic anhydride copolymer available from Cray Valley with trade names SMA1440, SMA17352, SMA2625, SMA3840 or SMA31890.

The styrene maleic anhydride resin may be added independently or in combination into the resin composition in one embodiment of the present invention. In one embodiment, when the resin composition comprise the styrene maleic anhydride resin, the content of the styrene maleic anhydride resin may be 1 part by weight to 20 parts by weight, 1 part by weight to 10 parts by weight, or 1 part by weight to 5 parts by weight. In another embodiment, the resin composition may not comprise the styrene maleic anhydride resin, and at this time the content of the styrene maleic anhydride resin is 0 parts by weight. However, the present invention is not limited thereto, and the content of the styrene maleic anhydride resin may be adjusted according to the needs.

In one embodiment, the benzoxazine resin may be bisphenol A type benzoxazine resin, bisphenol F type benzoxazine resin, phenolphthalein benzoxazine resin, dicyclopentadiene benzoxazine resin or phosphorus-containing benzoxazine resin, such as LZ-8270 (phenolphthalein benzoxazine resin), LZ-8280 (bisphenol F type benzoxazine resin) or LZ-8290 (bisphenol A type benzoxazine resin) available from Huntsman, or HFB-2006M available from Showa polymer co., Ltd. In another embodiment, when the resin composition comprises the benzoxazine resin, the content of the benzoxazine resin may be 1 part by weight to 10 parts by weight, 1 part by weight to 5 parts by weight or 1 part by weight to 3 parts by weight. In further another embodiment, the resin composition may not comprise the benzoxazine resin, and at this time the content of the benzoxazine resin is 0 parts by weight. However, the present invention is not limited thereto, and the content of the benzoxazine resin may be adjusted according to the needs.

In one embodiment, the cyanate ester resin may be any cyanate ester resin known in the art, wherein the cyanate ester resin may comprise, but are not limited to cyanate ester resin with Ar—O—C≡N structure (wherein, Ar is an aryl group such as phenyl, naphthyl or anthracenyl), phenol novolac cyanate ester resin, bisphenol A type cyanate ester resin, bisphenol A novolac cyanate ester resin, bisphenol F type cyanate ester resin, bisphenol F novolac cyanate ester resin, dicyclopentadiene-containing cyanate ester resin, naphthalene-containing cyanate ester resin or phenolphthalein type cyanate ester resin. Specific examples of the cyanate ester resin may comprise, but are not limited to the cyanate ester resin available from Lonza with trade names Primaset PT-15, PT-30S, PT-60S, BA-200, BA-230S, BA-3000S, BTP-2500, BTP-6020S, DT-4000, DT-7000, ULL950S, HTL-300, CE-320, LVT-50 or LeCy. In another embodiment, when the resin composition comprises the cyanate ester resin, the content of the cyanate ester resin may be 1 part by weight to 10 parts by weight, 1 part by weight to 5 parts by weight or 1 part by weight to 3 parts by weight. In further another embodiment, the resin composition may not comprise the cyanate ester resin, and at this time the content of the cyanate ester resin is 0 parts by weight. However, the present invention is not limited thereto, and the content of the cyanate ester resin may be adjusted according to the needs.

In one embodiment, the resin composition may further comprise polysiloxane resin (hereinafter, referred to as polysiloxane). In another embodiment, the resin composition may not comprise the polysiloxane, and at this time the content of the polysiloxane is 0 parts by weight; here, it means that the polysiloxane is not intentionally added into the resin composition. In further another embodiment, when the resin composition comprises the polysiloxane, the content of the polysiloxane may be 5 parts by weight to 30 parts by weight, for example, 5 parts by weight, 10 parts by weight or 15 parts by weight. However, the present invention is not limited thereto, and the content of the polysiloxane may be adjusted according to the needs. Specific examples of the polysiloxane may comprise, but are not limited to the polysiloxane produced by Shin-Etsu Corporation with trade names X-22-161A, X-22-161B, X-22-163A, X-22-163B or X-22-164.

In one embodiment, the resin composition may further comprises an inorganic filler, a solvent, a siloxane compound, an inhibitor, a flame retardant, a colorant, a toughener or a core-shell rubber. The aforesaid components may be used alone or in combination.

In one embodiment, the resin composition may further comprise an inorganic filler, and the content of the inorganic filler is not limited. In another embodiment, with respect to 100 parts by weight of the vinyl-containing polyphenylene ether resin, the resin composition may further comprise 50 parts by weight to 350 parts by weight of the inorganic filler, 150 parts by weight to 350 parts by weight of the inorganic filler, or 151 parts by weight to 335 parts by weight of the inorganic filler. However, the present invention is not limited thereto, and the content of the inorganic filler may be adjusted according to the needs.

In one embodiment, the inorganic filler may be silica. In one embodiment, the inorganic filler may be spherical silica. The spherical silica may include various types of spherical silica known in the art, and the particle size distribution D50 of the spherical silica may be, for example, less than or equal to 2.0 μm. For example, the particle size distribution D50 of the spherical silica may preferably range from 0.2 μm to 2.0 μm, for example, but not limited to 0.2 μm, 0.3 μm, 0.4 μm, 0.6 μm, 0.8 μm, 1.2 μm, 1.3 μm or 2.0 μm. The particle size distribution D50 refers to the particle size corresponding to the cumulative volume distribution of fillers (such as but not limited to spherical silica) reaching 50% as measured by laser scattering. The spherical silica suitable for the present invention is not particularly limited, and may be any one or more commercially available products, such as but not limited to spherical silica purchased from Admatechs Company.

In one embodiment, the spherical silica may optionally be pretreated with siloxane if it is needed. Siloxane may comprise amino silane, epoxy silane, vinyl silane, ester silane, hydroxysilane, isocyanurate silane, methacryloxysilane or acryloxysilane. With respect to 100 parts by weight of the spherical silica, the amount of the aforesaid siloxane for pretreatment may range from 0.005 parts by weight to 0.5 parts by weight, but the present invention is not limited thereto. The amount of the siloxane is not particularly limited, and the adding amount of the siloxane may be adjusted according to the dispersion of the inorganic filler in the resin composition.

In one embodiment, the inorganic filler other than the spherical silica may comprise, but are not limited to, non-spherical silica (that is, the known irregular type silica, and the irregular type silica is not spherical silica), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate modified talc, zinc oxide, zirconia, mica, boehmite (AlOOH), calcined talc, talc, silicon nitride or calcined kaolin. In addition, except for the aforementioned non-spherical silica, the rest of the aforementioned inorganic fillers can be spherical, fibrous, plate-like, granular, flake-like, needle-like or whisker-like. The inorganic fillers other than the spherical silica may selectively be pretreated with siloxane if it is needed. The examples and amount of the siloxane used to pretreat the inorganic fillers are as mentioned above, and are not repeated here.

In one embodiment, the resin composition may further comprise an inhibitor, and the content of the inhibitor is not particularly limited. In another embodiment, with respect to 100 parts by weight of the vinyl-containing polyphenylene ether resin, the resin composition may further comprise 0.01 parts by weight to 0.5 parts by weight of the inhibitor, but the present invention is not limited thereto. In further another embodiment, the resin composition may not comprise the inhibitor, and at this time the content of the inhibitor is 0 parts by weight; here, it means that the inhibitor is not intentionally added into the resin composition. In further another embodiment, when the resin composition comprises the inhibitor, the content of the inhibitor may be 0.01 parts by weight to 0.5 parts by weight, for example, 0.02 parts by weight, 0.05 parts by weight, 0.2 parts by weight, 0.3 parts by weight, 0.45 parts by weight or 0.5 parts by weight. However, the present invention is not limited thereto, and the content of the inhibitor may be adjusted according to the needs.

The inhibitor in the resin composition may be any one or more inhibitors suitable for making prepregs, resin films, laminates or printed circuit boards. The inhibitor may include various molecular polymerization inhibitors or stable free radical polymerization inhibitors known in the art. The molecular polymerization inhibitors may include, but are not limited to, phenolic compounds, quinone compounds, aromatic amine compounds, aromatic hydrocarbon nitro compounds, sulfur-containing compounds or variable-valent metal chlorides. More specifically, the molecular polymerization inhibitors may include, but are not limited to, phenol, hydroquinone, 4-tert-butylcatechol, benzoquinone, chloranil, 1,4-naphthoquinone, trimethylquinone, aniline, nitrobenzene, Na₂S, FeCl₃, or CuCl₂. The stable free radical polymerization inhibitors may include, but are not limited to, 1,1-diphenyl-2-trinitrophenylhydrazine (DPPH), triphenylmethyl free radical, 2,2,6,6-tetramethyl piperidine-1-oxide or derivatives of 2,2,6,6-tetramethylpiperidine-1-oxide.

In one embodiment, the resin composition may further comprise a flame retardant. In another embodiment, the resin composition may not comprise the flame retardant, and at this time the content of the flame retardant is 0 parts by weight; here, it means that the flame retardant is not intentionally added into the resin composition. In further another embodiment, when the resin composition comprises the flame retardant, the content of the flame retardant may be 30 parts by weight to 100 parts by weight, and for example, may be 30 parts by weight, 40 parts by weight, 50 parts by weight, 60 parts by weight, 70 parts by weight, 80 parts by weight, 90 parts by weight or 100 parts by weight. However, the present invention is not limited thereto, and the content of the flame retardant may be adjusted according to the needs.

The flame retardant in the resin composition may be any one or more flame retardants suitable for making prepregs, resin films, laminates or printed circuit boards, such as but not limited to phosphorus-containing flame retardants. For example, the phosphorus-containing flame retardants may comprise: ammonium polyphosphate, hydroquinone bis(diphenyl phosphate), bisphenol A bis(diphenylphosphate), tri (2-carboxyethyl) phosphine (TCEP), tris(chloroisopropyl)phosphate, trimethyl phosphate (TMP), dimethyl methyl phosphonate (DMMP), resorcinol bis(dixylenyl phosphate), RDXP (such as commercially available products PX-200, PX-201 or PX-202), phosphazene (such as commercially available products SPB-100, SPH-100 or SPV-100), melamine polyphosphate, 9,10-dihydro-9-oxa-10-phosphaphenanthrene-10-oxide (DOPO) or derivatives thereof (such as di-DOPO compound) or resin thereof (such as DOPO-HQ, DOPO-NQ, DOPO-PN or DOPO-BPN), DOPO-bonding epoxy resin, diphenylphosphine oxide (DPPO) or derivatives thereof (such as di-DPPO compound) or resin thereof, melamine cyanurate, tri-hydroxyethyl isocyanurate or aluminum phosphinate (such as commercially available products OP-930 or OP-935). Herein, DOPO-PN is DOPO phenol novolak resin, DOPO-BPN may be DOPO bisphenol novolac resin such as DOPO-BPAN (DOPO-bisphenol A novolac), DOPO-BPFN (DOPO-bisphenol F novolac) or DOPO-BPSN (DOPO-bisphenol S novolac).

In one embodiment, the content of the colorant, the toughener or the core-shell rubber may respectively be 0.01 parts by weight to 10 parts by weight, for example, but are not limited to 0.01 parts by weight to 3 parts by weight or 0.05 parts by weight to 1 part by weight. However, the present invention is not limited thereto, and the contents of the aforesaid components may be adjusted according to the needs.

The main function of adding solvent is to dissolve the components in the resin composition, change the solid content of the resin composition, and adjust the viscosity of the resin composition. Examples of the solvent may include, but are not limited to, methanol, ethanol, ethylene glycol monomethyl ether, acetone, butanone (also known as methyl ethyl ketone), methyl isobutyl ketone, cyclohexanone, toluene, xylene, methoxyethyl acetate, ethoxyethyl acetate, propoxyethyl acetate, ethyl acetate, propylene glycol methyl ether, dimethylformamide, dimethylacetamide, nitromethylpyrrolidone or a combination thereof. The adding amount of the aforesaid solvent is not particularly limited, and may be adjusted according to the desired viscosity of the resin composition. If a solvent is added to the resin composition, the solvent will evaporate and be removed when the resin composition is heated to a high temperature to form a semi-cured state. Therefore, there is no solvent in the prepreg or the resin film, or there is only a trace amount of solvent in the prepreg or the resin film.

The colorant suitable for use in the present invention may include, but is not limited to, dyes or pigments.

The main function of the toughener is to improve the toughness of the resin composition. The toughener suitable for the present invention may include, but are not limited to, carboxyl-terminated butadiene acrylonitrile rubber (CTBN) and other rubbers.

The core-shell rubber suitable for the present invention may include various commercially available core-shell rubbers.

The resin composition according to one embodiment of the present invention can be made into various products through various processing methods, including but not limited to prepregs, resin films, laminates or printed circuit boards.

For example, the resin composition provided by one embodiment the present invention can be used to prepare a prepreg, which may include a reinforcing material and a layered structure disposed thereon. The layered structure may be formed by heating the aforementioned resin composition to a high temperature to form a semi-cured state (B-stage). The baking temperature for preparing the prepreg may be between 110° C. and 150° C., and preferably between 120° C. and 140° C. The baking time may be 2 minutes to 6 minutes, and preferably 3 minutes to 5 minutes. The reinforcing material may be any one of fiber material, woven fabric, and non-woven fabric, and the woven fabric preferably includes glass fiber fabric. The type of the glass fiber fabric is not particularly limited, and can be various commercially available glass fiber fabrics that can be used for printed circuit boards, such as E-type glass fiber fabric, D-type glass fiber fabric, S-type glass fiber fabric, T-type glass fiber fabric, L-type glass fiber fabric or Q-type quartz fiber fabric, wherein the types of fibers may include yarn or roving, and the form may include spread form or standard form. The non-woven fabric preferably includes liquid crystal resin non-woven fabric or quartz non-woven fabric. The liquid crystal resin non-woven fabric may be, for example, polyester non-woven fabric, polyurethane non-woven fabric, etc., and is not limited thereto. The woven fabric may also include liquid crystal resin woven fabric, such as polyester woven fabric or polyurethane woven fabric, and is not limited thereto. The reinforcing material can increase the mechanical strength of the prepreg. In one preferred embodiment, the reinforcing material may also be selectively pretreated with a siloxane compound. After the prepreg is subsequently heated for curing (C-stage), an insulating layer can be formed.

For example, the resin composition of one embodiment of the present invention may be made into a resin film, which is obtained by heating and baking to semi-cure the resin composition, and the baking temperature for preparing the resin film may be between 110° C. to 150° C. The resin composition may be selectively applied on a polyethylene terephthalate film (PET film), a polyimide film (PI film), a copper foil or a resin-coated copper foil, followed by heating and baking to semi-cure the resin composition to form a resin film.

For example, the resin composition of one embodiment of the present invention can be made into a laminate. For example, the laminate may include at least two metal foils and at least one insulating layer, the insulating layer is disposed between the two metal foils, and the insulating layer may be formed by laminating and curing the aforementioned resin composition at high temperature and under high pressure (C-stage). The suitable curing temperature may be, for example, between 200° C. and 240° C., and preferably between 210° C. and 230° C.; the curing time may be 100 minutes to 200 minutes, and preferably 120 minutes to 180 minutes; and the suitable pressure may be 400 psi to 600 psi, and preferably 450 psi to 550 psi. The insulating layer may be obtained by curing at least one prepreg or at least one resin film. The metal foil can be made of copper, aluminum, nickel, platinum, silver, gold or alloys thereof. For example, the metal foil may be a copper foil. In a preferred embodiment, the laminate is a copper-clad laminate.

For example, the metal foil used in the laminate may be a hyper very low profile (HVLP) copper foil or a hyper very low profile 2 (HVLP2) copper foil. The matte side of the HVLP copper foil has a roughness Rz1, 1.5 (μm)≤Rz1≤2 (μm), the matte side of the HVLP2 copper foil has a roughness Rz2, 1.0 (μm)≤Rz2≤1.5 (μm), and the matte side of the HVLP3 copper foil has a roughness Rz3, Rz3≤1 (μm). The definition of the roughness Rz is the same as the general definition in the technical field of the copper foil, and is not repeated here.

For example, in one embodiment, the aforementioned laminate can be further processed into a printed circuit board after circuit processing, and the manufacturing method of the printed circuit board can be any known manufacturing method.

The chemical materials used in the following embodiments and comparative embodiments of the present invention are as follows.

SA9000: methacrylate-containing polyphenylene ether resin, commercially available.

OPE-2st 2200: vinylbenzyl biphenyl-containing polyphenylene ether resin, commercially available.

OPE-2st 1200: vinylbenzyl biphenyl-containing polyphenylene ether resin, commercially available.

Compound of the formula (1-1): commercially available.

Compound of the formula (2-1): commercially available.

25B: 2,5-dimethyl-2,5-di(tert-butylperoxy)-3-hexyne, commercially available.

DCP: dicumyl peroxide, commercially available.

BPO: benzoyl peroxide, commercially available.

BMI-70: bis(3-ethyl-5-methyl-4-maleiminobenzene) methane, commercially available.

BMI-2300: polyphenylmethane maleimide, commercially available.

Compound of the formula (3): commercially available.

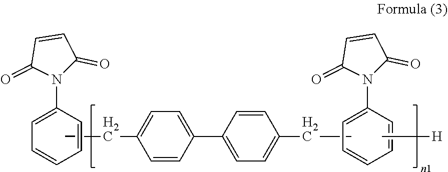

Wherein, n1 is a positive integer from 1 to 10.

Compound of the formula (4): commercially available.

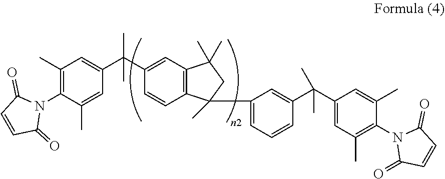

Wherein, n2 is a positive integer from 1 to 10.

Compound of the formula (5): commercially available.

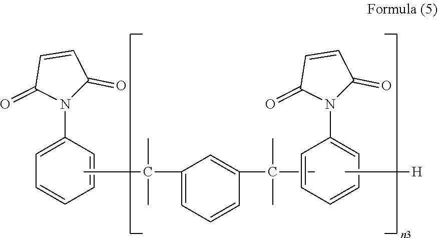

Wherein, n3 is a positive integer from 1 to 10.

Divinylbenzene-ethylstyrene-styrene terpolymer, commercially available.

Ricon 257: styrene-butadiene-divinylbenzene terpolymer, commercially available.

Ricon 150: polybutadiene, commercially available.

Ricon 100: styrene-butadiene copolymer, commercially available.

H1051: hydrogenated styrene-butadiene-styrene block copolymer, commercially available.

H1053: hydrogenated styrene-butadiene-styrene block copolymer, commercially available.

Triallyl isocyanurate: commercially available.

Divinylbenzene: commercially available.

Di(vinylphenyl)ethane: commercially available.

Diallyl isophthalate: commercially available.

SC2050 SVJ: spherical silica, commercially available.

SC2050 SMJ: spherical silica, commercially available.

CFP007ST: hexagonal boron nitride, commercially available.

Butanone and toluene: commercially available.

The resin compositions of Embodiments and Comparative embodiments of the present invention were prepared according to the amounts of the above-mentioned various raw materials listed in Table 1 to Table 4 below, and further prepared into various test samples.

TABLE 1
The components of the resin composition of Embodiments E1 to E4 (unit: parts by weight)

| Material | Component | Name | E1 | E2 | E3 | E4 |
|---|---|---|---|---|---|---|
| Vinyl-containing | Methacrylate-containing | SA9000 | 100 | 100 | 100 | 100 |
| polyphenylene | polyphenylene ether | | | | | |
| ether resin | Vinylbenzyl biphenyl- | OPE-2st 2200 | | | | |
| | containing polyphenylene | | | | | |
| | ether | | | | | |
| | Vinylbenzyl biphenyl- | OPE-2st 1200 | | | | |
| | containing polyphenylene | | | | | |
| | ether | | | | | |
| Reaction initiator | Formula (1) | Formula (1-1) | 8.3 | 13.3 | 6.7 | 10 |
| | Formula (2) | Formula (2-1) | 1.7 | 1.3 | 2.5 | 2 |
| | Peroxide | 25B | | | | |
| | | DCP | | | | |
| | | BPO | | | | |
| Maleimide | Maleimide 1 | BMI-70 | 33.3 | 41.7 | 26.7 | 28.3 |
| | Maleimide 2 | BMI-2300 | | | | |
| | Maleimide 3 | Formula (3) | | | | 10.0 |
| | Maleimide 4 | Formula (4) | | | | |
| | Maleimide 5 | Formula (5) | | | | |
| Divinylbenzene | Divinylbenzene-ethylstyrene-styrene | | 16.7 | 20 | 13.3 | |
| terpolymer | terpolymer | | | | | |
| | Styrene-butadiene- | Ricon 257 | | | | |
| | divinylbenzene terpolymer | | | | | |
| Polyolefin | Polybutadiene | Ricon 150 | | | | |
| | Styrene-butadiene | Ricon 100 | | | | |
| | copolymer | | | | | |
| | Hydrogenated styrene- | H1051 | 25 | 18.3 | 28.3 | |
| | butadiene-styrene tri-block | | | | | |
| | copolymer | | | | | |
| | Hydrogenated styrene- | H1053 | | | | 21.7 |
| | butadiene-styrene tri-block | | | | | |
| | copolymer | | | | | |
| Additive | Triallyl isocyanurate | | | | | |
| | Divinylbenzene | | | | | |
| | Di(vinylphenyl)ethane | | | | | |
| | Diallyl isophthalate | | | | | |
| Inorganic filler | Spherical silica | SC2050 SVJ | 222 | 234 | 214 | 146 |
| | | SC2050 SMJ | | | | |
| | Hexagonal boron nitride | CFP007ST | | | | 5 |

| | | | | | |
|---|---|---|---|---|---|
| Solvent | Butanone | 100 | 100 | 100 | 100 |
| | Toluene | 100 | 100 | 100 | 100 |

| Characteristics | Test condition | Unit | E1 | E2 | E3 | E4 |
|---|---|---|---|---|---|---|
| Dk1 @10 GHz | Room temperature | N/A | 3.07 | 3.07 | 3.07 | 3.07 |
| Df1 @10 GHz | Room temperature | N/A | 0.00263 | 0.00259 | 0.00257 | 0.00255 |
| Dk2 @10 GHz | Placing at room | N/A | 3.13 | 3.11 | 3.12 | 3.11 |
| | temperature for 240 hr | | | | | |
| Df2 @10 GHz | Placing at room | N/A | 0.00287 | 0.00282 | 0.00281 | 0.00276 |
| | temperature for 240 hr | | | | | |
| Dk3 @10 GHz | PCT moisture absorption | N/A | 3.16 | 3.16 | 3.15 | 3.15 |
| | for 3 hr | | | | | |
| Df3 @10 GHz | PCT moisture absorption | N/A | 0.00488 | 0.00479 | 0.00476 | 0.00462 |
| | for 3 hr | | | | | |
| Plate viscosity | Viscosity at Day 1 | Pa · s | 18289 | 18012 | 19057 | 18366 |
| (125° C., 2″40) | Viscosity at Day 17 | Pa · s | 20395 | 20024 | 21099 | 20240 |
| | Viscosity storage period | % | 11.5 | 11.2 | 10.7 | 10.2 |
| | change rate of prepreg | | | | | |
| P/S | | lb/in | 3.00 | 3.05 | 3.02 | 2.96 |
| B/S | | lb/in | 3.72 | 3.78 | 3.65 | 3.57 |
| PTE | Z-axis PTE | % | 1.51 | 1.49 | 1.65 | 1.48 |
| PCT heat | | N/A | ◯◯◯ | ◯◯◯ | ◯◯◯ | ◯◯◯ |
| resistance | | | | | | |
| Appearance of | Visual inspection | N/A | OK | OK | OK | OK |
| copper-free | | | | | | |
| laminate | | | | | | |

TABLE 2
The components of the resin composition of Embodiments E5 to E8 (unit: parts by weight)

| Material | Component | Name | E5 | E6 | E7 | E8 |
|---|---|---|---|---|---|---|
| Vinyl-containing | Methacrylate-containing | SA9000 | 100 | 100 | 100 | 75 |
| polyphenylene | polyphenylene ether | | | | | |
| ether resin | Vinylbenzyl biphenyl- | OPE-2st 2200 | | | | 15 |
| | containing polyphenylene | | | | | |
| | ether | | | | | |
| | Vinylbenzyl biphenyl- | OPE-2st 1200 | | | | 10 |
| | containing polyphenylene | | | | | |
| | ether | | | | | |
| Reaction initiator | Formula (1) | Formula (1-1) | 7.5 | 8 | 9.2 | 20 |
| | Formula (2) | Formula (2-1) | 1.7 | 2 | 2 | 0.5 |
| | Peroxide | 25B | | | | |
| | | DCP | | | | |
| | | BPO | | | | |
| Maleimide | Maleimide 1 | BMI-70 | | | | |
| | Maleimide 2 | BMI-2300 | 8.3 | | | |
| | Maleimide 3 | Formula (3) | | | | |
| | Maleimide 4 | Formula (4) | | 16.7 | | 10 |
| | Maleimide 5 | Formula (5) | 8.3 | 16.7 | | |
| Divinylbenzene | Divinylbenzene-ethylstyrene-styrene | | 13.3 | 8.3 | 8.3 | |
| terpolymer | terpolymer | | | | | |
| | Styrene-butadiene- | Ricon 257 | 16.7 | | | |
| | divinylbenzene terpolymer | | | | | |
| Polyolefin | Polybutadiene | Ricon 150 | | 3.3 | | 5 |
| | Styrene-butadiene | Ricon 100 | | 3.3 | | |
| | copolymer | | | | | |
| | Hydrogenated styrene- | H1051 | 25 | | 5 | |
| | butadiene-styrene tri-block | | | | | |
| | copolymer | | | | | |
| | Hydrogenated styrene- | H1053 | 5 | 10 | 3.3 | 5 |
| | butadiene-styrene tri-block | | | | | |
| | copolymer | | | | | |
| Additive | Triallyl isocyanurate | | | 3.3 | | 5 |
| | Divinylbenzene | | | 1.7 | | |
| | Di(vinylphenyl)ethane | | | | 16.7 | 10 |
| | Diallyl isophthalate | | | 1.7 | | |
| Inorganic filler | Spherical silica | SC2050 SVJ | 279 | 210 | 173 | 156 |
| | | SC2050 SMJ | 56 | | | |
| | Hexagonal boron nitride | CFP007ST | | | | |

| | | | | | |
|---|---|---|---|---|---|
| Solvent | Butanone | 100 | 100 | 70 | 30 |
| | Toluene | 100 | 100 | 140 | 120 |

| Characteristics | Test condition | Unit | E5 | E6 | E7 | E8 |
|---|---|---|---|---|---|---|
| Dk1 @10 GHz | Room temperature | N/A | 3.08 | 3.08 | 3.09 | 3.08 |
| Df1 @10 GHz | Room temperature | N/A | 0.00258 | 0.00268 | 0.00269 | 0.00272 |
| Dk2 @10 GHz | Placing at room | N/A | 3.12 | 3.12 | 3.13 | 3.12 |
| | temperature for 240 hr | | | | | |
| Df2 @10 GHz | Placing at room | N/A | 0.00282 | 0.00285 | 0.00289 | 0.00292 |
| | temperature for 240 hr | | | | | |
| Dk3 @10 GHz | PCT moisture absorption | N/A | 3.15 | 3.17 | 3.16 | 3.16 |
| | for 3 hr | | | | | |
| Df3 @10 GHz | PCT moisture absorption | N/A | 0.00475 | 0.00482 | 0.00486 | 0.00489 |
| | for 3 hr | | | | | |
| Plate viscosity | Viscosity at Day 1 | Pa · s | 18965 | 16366 | 12540 | 13850 |
| (125° C., 2″40) | Viscosity at Day 17 | Pa · s | 20855 | 17188 | 13235 | 14612 |
| | Viscosity storage period | % | 10.0 | 5.0 | 5.5 | 5.5 |
| | change rate of prepreg | | | | | |
| P/S | | lb/in | 2.95 | 3.15 | 3.23 | 3.28 |
| B/S | | lb/in | 3.61 | 3.77 | 3.90 | 3.83 |
| PTE | Z-axis PTE | % | 1.64 | 1.61 | 1.43 | 1.45 |
| PCT heat | | N/A | ◯◯◯ | ◯◯◯ | ◯◯◯ | ◯◯◯ |
| resistance | | | | | | |
| Appearance of | Visual inspection | N/A | OK | OK | OK | OK |
| copper-free | | | | | | |
| laminate | | | | | | |

TABLE 3
The components of the resin composition of Comparative embodiments C1 to C5 (unit: parts by weight)

| Material | Component | Name | C1 | C2 | C3 | C4 | C5 |
|---|---|---|---|---|---|---|---|
| Vinyl-containing | Methacrylate-containing | SA9000 | 100 | 100 | 100 | 100 | 100 |
| polyphenylene | polyphenylene ether | | | | | | |
| ether resin | Vinylbenzyl biphenyl- | OPE-2st 2200 | | | | | |
| | containing polyphenylene | | | | | | |
| | ether | | | | | | |
| | Vinylbenzyl biphenyl- | OPE-2st 1200 | | | | | |
| | containing polyphenylene | | | | | | |
| | ether | | | | | | |
| Reaction initiator | Formula (1) | Formula (1-1) | 8.3 | | | | |
| | Formula (2) | Formula (2-1) | | 3.3 | | | |
| | Peroxide | 25B | | | 1 | 1.7 | 3.3 |
| | | DCP | | | | | |
| | | BPO | | | | | |
| Maleimide | Maleimide 1 | BMI-70 | 33.3 | 33.3 | 33.3 | 33.3 | 33.3 |
| | Maleimide 2 | BMI-2300 | | | | | |
| | Maleimide 3 | Formula (3) | | | | | |
| | Maleimide 4 | Formula (4) | | | | | |
| | Maleimide 5 | Formula (5) | | | | | |

| | | | | | | |
|---|---|---|---|---|---|---|
| Divinylbenzene | Divinylbenzene-ethylstyrene-styrene | 16.7 | 16.7 | 16.7 | 16.7 | 16.7 |
| terpolymer | terpolymer | | | | | |

| | | | | | | | |
|---|---|---|---|---|---|---|---|
| | Styrene-butadiene- | Ricon 257 | | | | | |
| | divinylbenzene terpolymer | | | | | | |
| Polyolefin | Polybutadiene | Ricon 150 | | | | | |
| | Styrene-butadiene | Ricon 100 | | | | | |
| | copolymer | | | | | | |
| | Hydrogenated styrene- | H1051 | 25 | 25 | 25 | 25 | 25 |
| | butadiene-styrene tri-block | | | | | | |
| | copolymer | | | | | | |
| | Hydrogenated styrene- | H1053 | | | | | |
| | butadiene-styrene tri-block | | | | | | |
| | copolymer | | | | | | |

| | |
|---|---|
| Additive | Triallyl isocyanurate |
| | Divinylbenzene |
| | Di(vinylphenyl)ethane |
| | Diallyl isophthalate |

| | | | | | | | |
|---|---|---|---|---|---|---|---|
| Inorganic filler | Spherical silica | SC2050 SVJ | 222 | 222 | 222 | 222 | 222 |
| | | SC2050 SMJ | | | | | |
| | Hexagonal boron nitride | CFP007ST | | | | | |

| | | | | | | |
|---|---|---|---|---|---|---|
| Solvent | Butanone | 100 | 100 | 100 | 100 | 100 |
| | Toluene | 100 | 100 | 100 | 100 | 100 |

| Characteristics | Test condition | Unit | C1 | C2 | C3 | C4 | C5 |
|---|---|---|---|---|---|---|---|
| Dk1 @10 GHz | Room temperature | N/A | 3.15 | 3.13 | 3.14 | 3.16 | 3.17 |
| Df1 @10 GHz | Room temperature | N/A | 0.00263 | 0.00311 | 0.00324 | 0.00363 | 0.00416 |
| Dk2 @10 GHz | Placing at room temperature | N/A | 3.16 | 3.14 | 3.16 | 3.17 | 3.18 |
| | for 240 hr | | | | | | |
| Df2 @10 GHz | Placing at room temperature | N/A | 0.00277 | 0.00325 | 0.00344 | 0.00391 | 0.00453 |
| | for 240 hr | | | | | | |
| Dk3 @10 GHz | PCT moisture absorption for | N/A | 3.23 | 3.15 | 3.16 | 3.16 | 3.17 |
| | 3 hr | | | | | | |
| Df3 @10 GHz | PCT moisture absorption for | N/A | 0.00679 | 0.00513 | 0.00581 | 0.00624 | 0.00695 |
| | 3 hr | | | | | | |
| Plate viscosity | Viscosity at Day 1 | Pa · s | 8112 | 41370 | 21465 | 23158 | 25057 |
| (125° C., 2″40) | Viscosity at Day 17 | Pa · s | 9290 | 60085 | 44073 | 47998 | 48990 |
| | Viscosity storage period | % | 14.5 | 45.2 | 105.3 | 107.3 | 95.5 |
| | change rate of prepreg | | | | | | |
| P/S | | lb/in | 2.73 | 2.32 | 2.51 | 2.94 | 2.59 |
| B/S | | lb/in | 2.28 | 2.48 | 2.35 | 3.17 | 2.39 |
| PTE | Z-axis PTE | % | 2.58 | 2.03 | 2.02 | 1.84 | 1.85 |
| PCT heat | | N/A | ◯◯X | ◯◯◯ | ◯◯◯ | ◯◯◯ | XXX |
| resistance | | | | | | | |
| Appearance of | Visual inspection | N/A | OK | OK | OK | OK | NG |
| copper-free | | | | | | | |
| laminate | | | | | | | |

TABLE 4
The components of the resin composition of Comparative embodiments C6 to C10 (unit: parts by weight)

| Material | Component | Name | C6 | C7 | C8 | C9 | C10 |
|---|---|---|---|---|---|---|---|
| Vinyl-containing | Methacrylate-containing | SA9000 | 100 | 100 | 100 | 100 | 100 |
| polyphenylene | polyphenylene ether | | | | | | |
| ether resin | Vinylbenzyl biphenyl- | OPE-2st 2200 | | | | | |
| | containing polyphenylene | | | | | | |
| | ether | | | | | | |
| | Vinylbenzyl biphenyl- | OPE-2st 1200 | | | | | |
| | containing polyphenylene | | | | | | |
| | ether | | | | | | |
| Reaction initiator | Formula (1) | Formula (1-1) | 8.3 | | 8.3 | 10 | |
| | Formula (2) | Formula (2-1) | | 1.7 | | | 10 |
| | Peroxide | 25B | 0.3 | 0.2 | 0.5 | | |
| | | DCP | 0.5 | 0.5 | 0.5 | | |
| | | BPO | | 0.3 | 0.7 | | |
| Maleimide | Maleimide 1 | BMI-70 | 33.3 | 33.3 | 33.3 | 33.3 | 33.3 |
| | Maleimide 2 | BMI-2300 | | | | | |
| | Maleimide 3 | Formula (3) | | | | | |
| | Maleimide 4 | Formula (4) | | | | | |
| | Maleimide 5 | Formula (5) | | | | | |

| | | | | | | |
|---|---|---|---|---|---|---|
| Divinylbenzene | Divinylbenzene-ethylstyrene-styrene | 16.7 | 16.7 | 16.7 | 16.7 | 16.7 |
| terpolymer | terpolymer | | | | | |

| | | | | | | | |
|---|---|---|---|---|---|---|---|
| | Styrene-butadiene- | Ricon 257 | | | | | |
| | divinylbenzene terpolymer | | | | | | |
| Polyolefin | Polybutadiene | Ricon 150 | | | | | |
| | Styrene-butadiene copolymer | Ricon 100 | | | | | |
| | Hydrogenated styrene- | H1051 | 25 | 25 | 25 | 25 | 25 |
| | butadiene-styrene tri-block | | | | | | |
| | copolymer | | | | | | |
| | Hydrogenated styrene- | H1053 | | | | | |
| | butadiene-styrene tri-block | | | | | | |
| | copolymer | | | | | | |

| | |
|---|---|
| Additive | Triallyl isocyanurate |
| | Divinylbenzene |
| | Di(vinylphenyl)ethane |
| | Diallyl isophthalate |

| | | | | | | | |
|---|---|---|---|---|---|---|---|
| Inorganic filler | Spherical silica | SC2050 SVJ | 222 | 222 | 222 | 222 | 222 |
| | | SC2050 SMJ | | | | | |
| | Hexagonal boron nitride | CFP007ST | | | | | |

| | | | | | | |
|---|---|---|---|---|---|---|
| Solvent | Butanone | 100 | 100 | 100 | 100 | 100 |
| | Toluene | 100 | 100 | 100 | 100 | 100 |

| Characteristics | Test condition | Unit | C6 | C7 | C8 | C9 | C10 |
|---|---|---|---|---|---|---|---|
| Dk1 @10 GHz | Room temperature | N/A | 3.14 | 3.14 | 3.15 | 3.15 | 3.13 |
| Df1 @10 GHz | Room temperature | N/A | 0.00319 | 0.00329 | 0.00368 | 0.00261 | 0.00309 |
| Dk2 @10 GHz | Placing at room temperature | N/A | 3.16 | 3.15 | 3.16 | 3.15 | 3.14 |
| | for 240 hr | | | | | | |
| Df2 @10 GHz | Placing at room temperature | N/A | 0.00339 | 0.00351 | 0.00399 | 0.00274 | 0.00324 |
| | for 240 hr | | | | | | |
| Dk3 @10 GHz | PCT moisture absorption for | N/A | 3.16 | 3.15 | 3.16 | 3.23 | 3.15 |
| | 3 hr | | | | | | |
| Df3 @10 GHz | PCT moisture absorption for | N/A | 0.00569 | 0.00585 | 0.00636 | 0.00672 | 0.00516 |
| | 3 hr | | | | | | |
| Plate viscosity | Viscosity at Day 1 | Pa · s | 21174 | 21844 | 23766 | 8333 | 41555 |
| (125° C., 2″40) | Viscosity at Day 17 | Pa · s | 43655 | 43996 | 48072 | 9498 | 60666 |
| | Viscosity storage period | % | 106.2 | 101.4 | 102.3 | 14. | 46.0 |
| | change rate of prepreg | | | | | | |
| P/S | | lb/in | 3.03 | 3.02 | 2.68 | 2.75 | 2.33 |
| B/S | | lb/in | 3.38 | 3.23 | 2.72 | 2.30 | 2.48 |
| PTE | Z-axis PTE | % | 1.69 | 1.62 | 1.63 | 2.62 | 2.05 |
| PCT heat | | N/A | ◯◯◯ | ◯◯◯ | XXX | ◯◯X | ◯XX |
| resistance | | | | | | | |
| Appearance of | Visual inspection | N/A | OK | OK | NG | OK | OK |
| copper-free | | | | | | | |
| laminate | | | | | | | |

### Varnish

According to the amounts shown Table 1 to Table 4, the components of each Embodiments (abbreviated as E, such as E1 to E8) and Comparative embodiments (abbreviated as C, such as C1 to C10) were respectively added into the stirring tank and stirred. After mixing uniformly, the obtained resin composition was called as a varnish.

The formulation method of the resin composition of Embodiment 1 (E1) is used as an example. First, an appropriate amount (parts by weight) of toluene was taken out from 100 parts by weight of toluene to dissolve 8.3 parts by weight of the compound of the formula (1-1) and 1.7 parts by weight of the compound of the formula (2-1) to obtain a solution containing the compound of the formula (1-1) and the compound of the formula (2-1). The appropriate amount (parts by weight) of the solvent is the common knowledge in the field of “solid chemical raw materials dissolved in solvents” and will not be described again here. Then, 100 parts by weight of SA9000, 33.3 parts by weight of BMI-70, 16.7 parts by weight of divinylbenzene-ethylstyrene-styrene terpolymer and 25 parts by weight of H1051 were added into the mixture containing 100 parts by weight of toluene (the aforementioned appropriate amount of toluene (parts by weight) has to be deducted) and 100 parts by weight of butanone in a stirring mixing tank, followed by stirring until all solid chemical raw materials (such as but not limited to SA9000) were completely dissolved and mixed evenly. After completely dissolving and mixing evenly by stirring, 222 parts by weight of SC2050 SVJ was added followed by continuously stirring until uniformly mixed. Then, the aforementioned solution containing the compound of the formula (1-1) and the compound of the formula (2-1) was added, followed by continuously stirring until uniformly mixed to obtain the varnish of the resin composition of Embodiment E1.

In addition, according to the amounts shown in Table 1 to Table 4, the varnishes of the resin compositions of Embodiments 2 to 8 (E2 to E8) and Comparative embodiments 1 to 10 (C1 to C10) were prepared with reference to the preparation method of the varnish of Embodiment 1 (E1).

With reference to the following methods, the varnishes of Embodiments 1 to 8 (E1 to E8) and Comparative embodiments 1 to 10 (C₁ to C₁₀) were used to prepare the samples to be tested (respectively including prepreg 1, prepreg 2, copper-containing laminate 1, copper-containing laminate 2, copper-free laminate 1 and copper-free laminate 2). Then, the characteristic analyses were performed according to the following specific conditions.

### Prepreg 1 (Using 2116 L-Glass Fiber Fabric)

The resin compositions in different Embodiments (E1 to E8) and Comparative embodiments (C1 to C10) listed in Table 1 to Table 4 were respectively put into an impregnation tank in batches. The glass fiber fabric (2116 L-glass fiber fabric) was passed through the above impregnation tank, and the resin compositions were adhered to the glass fiber fabric. After heating and baking at 125° C. for 2 minutes and 40 seconds, the resin compositions were turned into the semi-cured state (B-Stage) to obtain the prepreg 1 (the resin content is about 56%).

### Prepreg 2 (Using 1078 L-Glass Fiber Fabric)

The resin compositions in different Embodiments (E1 to E8) and Comparative embodiments (C1 to C10) listed in Table 1 to Table 4 were respectively put into an impregnation tank in batches. The glass fiber fabric (1078 L-glass fiber fabric) was passed through the above impregnation tank, and the resin compositions were adhered to the glass fiber fabric. After heating and baking at 125° C. for 2 minutes and 40 seconds, the resin compositions were turned into the semi-cured state (B-Stage) to obtain the prepreg 2 (the resin content is about 65%).

Copper-Containing Laminate 1 (or Called as Copper-Clad Laminate 1, which was Prepared by Laminating Six Prepregs 1)

Two hyper very low profile 3 (HVLP3) copper foils with a thickness of 18 μm and the same six aforementioned prepregs 1 were provided. One copper foil, six prepregs 1 and one copper foil were laminated in sequence, and the lamination was performed under a vacuum condition at 500 psi and 235° C. for 150 minutes to obtain a copper-containing laminate 1.

Copper-Containing Laminate 2 (or Called as Copper-Clad Laminate 2, which was Prepared by Laminating Two Prepregs 2)

Two hyper very low profile 3 (HVLP3) copper foils with a thickness of 18 μm and the same two aforementioned prepregs 2 were provided. One copper foil, two prepregs 2 and one copper foil were laminated in sequence, and the lamination was performed under a vacuum condition at 500 psi and 235° C. for 150 minutes to obtain a copper-containing laminate 2.

### Copper-Free Laminate 1

The aforesaid copper-containing laminate 1 was etched to remove the copper foils on both sides to obtain a copper-free laminate 1.

### Copper-Free Laminate 2

The aforesaid copper-containing laminate 2 was etched to remove the copper foils on both sides to obtain a copper-free laminate 2.

The test methods and characteristic analysis items for the aforementioned samples to be tested are explained as follows.

### Dielectric Constant (Dk1)

In the measurement of the dielectric constant, the aforesaid copper-free laminate 2 was used as the sample to be tested. The copper-free laminate 2 was cut into a long strip sample with a width of 3.5 mm (millimeter) and a length of 150 mm. The copper-free laminate 2 here was the copper-free laminate 2 fresh produced (Day 1). A microwave dielectrometer (available from Japan AET company) was used. According to the method described in JIS C₂₅₆₅, each sample to be tested was measured at room temperature (about 25° C.) and at a frequency of 10 GHz, to obtain the dielectric constant Dk1 (herein, the dielectric constant Dk1 and the dissipation factor Df1 can be measured simultaneously). The lower the dielectric constant, the better the dielectric property of the sample to be tested. At the measurement frequency of 10 GHZ, the difference in the Dk1 values of different samples to be tested less than 0.02 represents no significant difference in the dielectric constant of the laminates (no significant difference means that there is no significant technical difficulty), and the difference in the Dk1 values greater than or equal to 0.02 represents a significant difference in the dielectric constant of the laminates (there is significant technical difficulty). The dielectric constant Dk1 of the samples to be tested in Embodiments (E1 to E8) is between 3.05 and 3.10, and for example, the dielectric constant Dk1 is between 3.07 and 3.09.

Dielectric Constant after Placing at Room Temperature for 240 Hours (Dk2)

In the measurement of the dielectric constant after placing at room temperature for 240 hours (Dk2), the same long strip sample of the copper-free laminate 2 that was used in the measurement of the dielectric constant above (Dk1) was selected as the sample to be tested. The difference is that the copper-free laminate 2 fresh made on Day 1 was placed in a drying box, and the sample to be tested was taken out after being placed at room temperature (25° C.) for 240 hours (that is, placed for 10 days). Next, a microwave dielectrometer (available from Japan AET company) was used. According to the method described in JIS C2565, each sample to be tested was measured at room temperature (about 25° C.) and at a frequency of 10 GHz, to obtain the dielectric constant Dk2 after placing at room temperature for 240 hours (abbreviated as dielectric constant Dk2, and the dielectric constant Dk2 and the dissipation factor Df2 can be measured simultaneously). The lower the dielectric constant, the better the dielectric property of the sample to be tested. At the measurement frequency of 10 GHz, the difference in the Dk2 values of the different samples to be tested less than 0.02 represents no significant difference in the dielectric constant of the laminates (no significant difference means that there is no significant technical difficulty), and the difference in the Dk2 values greater than or equal to 0.02 represents a significant difference in the dielectric constant of the laminates (there is significant technical difficulty). The dielectric constant Dk2 of the samples to be tested in Embodiments (E1 to E8) is between 3.11 and 3.13.

Dielectric Constant after PCT Moisture Absorption for 3 hr (Dk3)

The copper-free laminate 2 produced on Day 1 was cut into a long strip sample with a width of 3.5 mm (millimeter) and a length of 150 mm. The copper-free laminate 2 here was the copper-free laminate 2 fresh produced (Day 1). Referring to the method described in IPC-TM-650 2.6.16.1, a pressure cooking test (PCT) was performed, and the sample to be tested absorbed moisture for 3 hours (the test temperature was 121° C., and the relative humidity was 100%). After taking out the sample, the remaining water (or moisture, if any) on the surface of the sample was removed to obtain the sample to be tested. Next, a microwave dielectrometer (available from Japan AET company) was used on the sample to be tested. According to the method described in JIS C2565, each sample to be tested was measured at room temperature (about 25° C.) and at a frequency of 10 GHZ, to obtain the dielectric constant 3 after PCT moisture absorption for 3 hours (abbreviated as dielectric constant Dk3, and the dielectric constant Dk3 and the dissipation factor Df3 can be measured simultaneously). The lower the dielectric constant, the better the dielectric property of the sample to be tested. At the measurement frequency of 10 GHz, the difference in the Dk3 values of different samples to be tested less than 0.02 represents no significant difference in the dielectric constant of the laminates (no significant difference means that there is no significant technical difficulty), and the difference in the Dk3 values greater than or equal to 0.02 represents a significant difference in the dielectric constant of the laminates (there is significant technical difficulty). The dielectric constant Dk3 of the samples to be tested in Embodiments (E1 to E8) is between 3.15 and 3.17. Dielectric constant Dk3 is the dielectric constant value under more severe moisture absorption conditions, which represents the variation degree of dielectric constant of copper-free laminates under more severe moisture absorption conditions. However, in the general process of making copper clad laminates into printed circuit boards, the copper clad laminates are not treated with the PCT moisture absorption process for 3 hours. This test is only a reference for evaluating the moisture absorption resistance of the copper clad laminates.

### Dissipation Factor (Df1)

In the measurement of the dissipation factor, the aforesaid copper-free laminate 2 was used. The copper-free laminate 2 was cut into a long strip sample with a width of 3.5 mm (millimeter) and a length of 150 mm. The copper-free laminate 2 here was the copper-free laminate 2 fresh produced (Day 1). A microwave dielectrometer (available from Japan AET company) was used. According to the method described in JIS C2565, each sample to be tested was measured at room temperature (about 25° C.) and at a frequency of 10 GHz, to obtain the dissipation factor Df1 (herein, the dielectric constant Dk1 and the dissipation factor Df1 can be measured simultaneously). The lower the dissipation factor, the better the dielectric property of the sample to be tested. At the measurement frequency of 10 GHz and the Df1 values of different samples to be tested less than or equal to 0.00400, the difference in the Df1 values less than 0.00010 represents no significant difference in the dissipation factor of the laminates (no significant difference means that there is no significant technical difficulty), and the difference in the Df1 values greater than or equal to 0.00010 represents a significant difference in the dielectric constant of the laminates (there is significant technical difficulty). At the measurement frequency of 10 GHz and the Df1 value of different samples to be tested greater than 0.00400, the difference in the Df1 values less than 0.00050 represents no significant difference in the dissipation factor of the laminates, and the difference in the Df1 values greater than or equal to 0.00050 represents a significant difference in the dielectric constant of the laminates. The dissipation factor Df1 of the samples to be tested in Embodiments (E1 to E8) measured at room temperature and a frequency of 10 GHz is between 0.00250 and 0.00300 (for example, the dissipation factor Df1 is between 0.00250 and 0.00280), and all the dissipation factor Df1 is less than or equal to 0.00300.

Dissipation Factor after Placing at Room Temperature for 240 Hours (Df2)

In the measurement of the dissipation factor after placing at room temperature for 240 hours (Df2), the same long strip sample of the copper-free laminate 2 that was used in the measurement of the dissipation factor above (Df1) was selected as the sample to be tested. The difference is that the copper-free laminate 2 fresh made on Day 1 was placed in a drying box, and the sample to be tested was taken out after being placed at room temperature (25° C.) for 240 hours (that is, placed for 10 days). Next, a microwave dielectrometer (available from Japan AET company) was used. According to the method described in JIS C2565, each sample to be tested was measured at room temperature (about 25° C.) and at a frequency of 10 GHz, to obtain the dissipation factor Df2 after placing at room temperature for 240 hours (abbreviated as dissipation factor Df2, the dielectric constant Dk2 and the dissipation factor Df2 can be measured simultaneously). The lower the dissipation factor, the better the dielectric property of the sample to be tested. At the measurement frequency of 10 GHz and the Df2 value less than 0.00400, the difference in the Df2 values less than 0.00010 represents no significant difference in the dissipation factor of the laminates (no significant difference means that there is no significant technical difficulty), and the difference in the Df2 values greater than or equal to 0.00010 represents a significant difference in the dielectric constant of the laminates (there is significant technical difficulty). At the measurement frequency of 10 GHz and the Df2 value greater than 0.00400, the difference in the Df2 values less than 0.00050 represents no significant difference in the dissipation factor of the laminates, and the difference in the Df2 values greater than or equal to 0.00050 represents a significant difference in the dielectric constant of the laminates. The dissipation factor Df2 of the samples to be tested in Embodiments (E1 to E8) measured at room temperature and a frequency of 10 GHz is between 0.00270 and 0.00300 (for example, the dissipation factor Df2 is between 0.00275 and 0.00295), and all the dissipation factor Df2 is less than or equal to 0.00300.

Dissipation Factor after PCT Moisture Absorption for 3 hr (Df3)

The copper-free laminate 2 produced on Day 1 was cut into a long strip sample with a width of 3.5 mm (millimeter) and a length of 150 mm. The copper-free laminate 2 here was the copper-free laminate 2 fresh produced (Day 1). Referring to the method described in IPC-TM-650 2.6.16.1, a pressure cooking test (PCT) was performed, and the sample to be tested absorbed moisture for 3 hours (the test temperature was 121° C., and the relative humidity was 100%). After taking out the sample, the remaining water (or moisture, if any) on the surface of the sample was removed to obtain the sample to be tested. Next, a microwave dielectrometer (available from Japan AET company) was used on the sample to be tested. According to the method described in JIS C2565, each sample to be tested was measured at room temperature (about 25° C.) and at a frequency of 10 GHZ, to obtain the dissipation factor Df3 after PCT moisture absorption for 3 hours (abbreviated as dissipation factor Df3, and the dielectric constant Dk3 and the dissipation factor Df3 can be measured simultaneously). The lower the dissipation factor, the better the dielectric property of the sample to be tested. At the measurement frequency of 10 GHz and the Df3 value less than 0.00400, the difference in the Df3 values less than 0.00010 represents no significant difference in the dissipation factor of the laminates (no significant difference means that there is no significant technical difficulty), and the difference in the Df3 values greater than or equal to 0.00010 represents a significant difference in the dielectric constant of the laminates (there is significant technical difficulty). At the measurement frequency of 10 GHz and the Df3 value greater than 0.00400, the difference in the Df3 values less than 0.00050 represents no significant difference in the dissipation factor of the laminates, and the difference in the Df3 values greater than or equal to 0.00050 represents a significant difference in the dielectric constant of the laminates. The dissipation factor Df3 of the samples to be tested in Embodiments (E1 to E8) is between 0.00460 and 0.00500 (for example, the dissipation factor Df3 is between 0.00460 and 0.00490), and all the dissipation factor Df3 is less than or equal to 0.00500. Dissipation factor Df3 is the dissipation factor value under more severe moisture absorption conditions, which represents the variation degree of dissipation factor of copper-free laminates under more severe moisture absorption conditions. However, in the general process of making copper clad laminates into printed circuit boards, the copper clad laminates are not treated with the PCT moisture absorption process for 3 hours. This test is only a reference for evaluating the moisture absorption resistance of the copper clad laminates.

### Viscosity Storage Period Test of Prepreg

The prepreg 1 fresh produced on Day 1 was provided. The user used his hands to knead the semi-cured resin layer on the prepreg 1 (Day 1) into powder. The semi-cured resin layer was separated from the glass fiber fabric, and the glass fiber fabric was screened out using a mesh to leave the powder. 0.15 g of the powder was weighted and its viscosity was measured using a high-shear cone viscometer (Research Equipment London's (REL) Analogue Viscometer, referred to as REL Viscometer) to obtain the viscosity 1 (Day 1), in Pa·s. Another prepreg 1 prepared on Day 1 was placed at room temperature for 17 days, and then the viscosity of the prepreg 1 (Day 1) was measured using the same method as above to obtain the viscosity 2 (Day 17), in Pa·s. The change rate of the viscosity 2 and the viscosity 1 was calculated to obtain the viscosity storage period change rate of the prepreg (viscosity change rate after 17 days of storage). The viscosity storage period change rate of the above prepreg=[(viscosity 2-viscosity 1)/viscosity 1]*100%, unit %. The smaller the viscosity storage period change rate of the prepreg, the better, which means that the viscosity of the prepreg will not increase significantly as the placing time increases. A prepreg with a smaller viscosity storage period change rate can still be used for manufacturing printed circuit boards after being placed for half a month. On the contrary, if the prepreg has a large viscosity storage period change rate, after being placed for half a month, when used in the manufacture of printed circuit boards, the glue filling performance of the prepreg will be poor, resulting in cavitation inside the laminate, thereby causing the printed circuit board to fail. If the quality of the printed circuit board fails, it must be scrapped.

### Peel Strength of Copper Foil (P/S)

The copper-containing laminate 1 was cut into a rectangular sample with a width of 24 mm and a length greater than 60 mm (If the following does not specify the day it was made or how many days it has been placed, it means that the test of copper-containing laminate or copper-free laminate will not be affected by the increase in the placement time of the laminate), and the copper foil thereon was etched to leave a strip copper foil with a width of 3.18 mm and a length greater than 60 mm. According to the method described in IPC-TM-650 2.4.8, an universal tensile strength testing machine was used to measure the force required to pull the copper foil away from the surface of the laminate (unit: 1b/inches, lb/in) at room temperature (about 25° C.). The higher the peel strength of copper foil, the better. The difference between the peel strength of copper foil of different samples to be tested using HVLP3 copper foil being greater than or equal to 0.05 lb/in represents a significant difference (there is significant technical difficulty). The peel strength of copper foil of the copper-containing laminates of Embodiments (E1 to E8) are all greater than or equal to 2.90 lb/in, for example, greater than or equal to 2.90 lb/in, further for example, between 2.90 lb/in and 3.30 lb/in or between 2.95 lb/in and 3.28.

### Bonding Strength of Laminate Interlayer (B/S)

The copper-containing laminate 1 was cut into a rectangular sample to be tested with a width of 12.7 mm and a length greater than 60 mm. According to the method described in IPC-TM-650 2.4.8, an universal tensile strength testing machine was used for measurement. The difference is that there is no need to etch the surface copper foil, and the test position is the joint surface between the third layer of the prepreg and the fourth layer of the prepreg. The bonding strength of laminate interlayer was obtained by measuring the force (unit: 1b/inches, lb/in) required to separate the above two layers of the cured insulating laminate at room temperature (approximately 25° C.). Generally, a significant difference exists when the difference of the bonding strength of laminate interlayer is greater than or equal to 0.10 pounds/inch. The higher the bonding strength of laminate interlayer, the better.

### Percentage of Thermal Expansion (PTE)

In the measurement of the percentage of thermal expansion (measuring the Z-axis direction of the copper-free laminate), a copper-free laminate 1 was selected as the sample to be tested for thermal mechanical analysis (TMA), and the sample was cut into a square sample with a width of 7 mm and a length of 7 mm. The sample was heated in the temperature range from 35° C. to 270° C. at a heating rate of 10° C. per minute. The percentage of thermal expansion at Z-axis (unit: %) of each sample to be tested in the temperature range from 50° C. to 260° C. was measured according to the method described in IPC-TM-650 2.4.24.5. The lower the percentage of thermal expansion, the better. Generally, a significant difference is considered when the difference in the percentage of thermal expansion at Z-axis is greater than or equal to 0.3%.

Heat Resistance Test after Moisture Absorption (PCT Heat Resistance)

The copper-free laminate 1 was cut into a rectangular sample to be tested with a width of 12.7 mm and a length of 60 mm. Referring to the method described in IPC-TM-650 2.6.16.1, a pressure cooking test (PCT) was performed, and the sample to be tested absorbed moisture for 5 hours (the test temperature was 121° C., and the relative humidity was 100%). Then, the remaining water (if any) on the surface of the sample was removed. Referring to the method described in IPC-TM-650 2.4.23, the sample to be tested was immersed in a tin furnace with a constant temperature of 288° C., and taken out after immersing for 20 seconds to check whether there is any explosion. For example, interlayer peeling between insulating layers is considered as board explosion. For example, bubbling and separation may be occurred between any layers of the laminate. Three samples were tested in sequence. If at least one of the samples is exploded, it fails. If all three samples are not exploded, it passes the test. If the test result of one sample is explosion, it will be marked as X. If the test result of one sample is not explosion, it will be marked as O. The test results of the three samples were recorded in sequence. For example, if three samples are exploded, it will be marked as XXX; and if three examples are not exploded, it will be marked as OOO.

### Appearance of Copper-Free Laminate

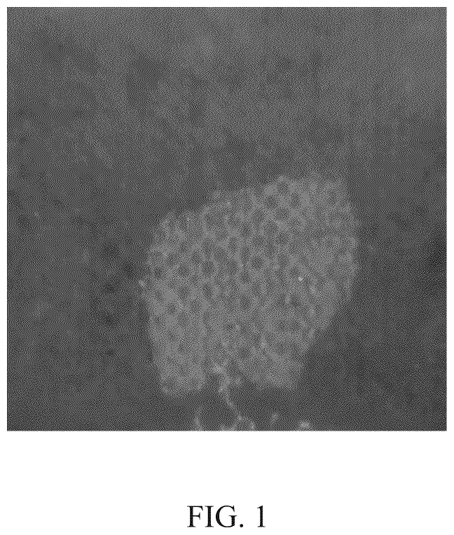

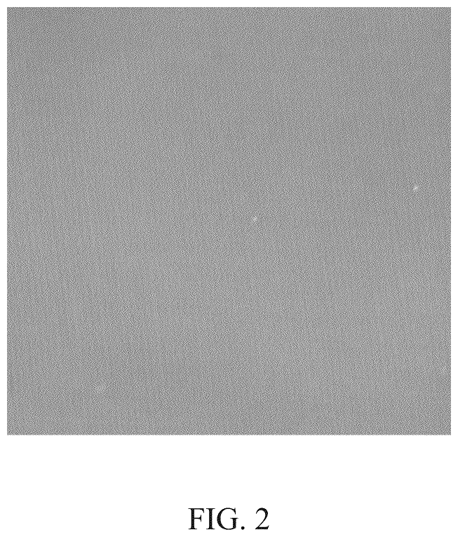

The surface condition of the insulating layer of the above-mentioned copper-free laminate 1 was determined by visual observation. The appearance of the surface insulation layer of the copper-free laminate was visually observed to determine if there was any dryness. The schematic diagram showing the distribution of the dryness is shown in FIG. 1. Dryness means that the surface of the insulation layer of the copper-free laminate 1 has exposed texture (or it is called lack of glue on the surface of the insulation layer). The schematic diagram showing the surface insulation layer of the copper-free laminate without dryness is shown in FIG. 2. The presence of dry areas on the surface insulation layer of the copper-free laminate may cause uneven characteristics (poor reliability) of subsequent circuit boards and significantly reduce the yield. For example, it may cause shortcomings such as poor dielectric properties, low heat resistance, uneven thermal expansion, or poor interlayer contact. Circuit boards with the aforementioned shortcomings will be scrapped directly. If the sample test result shows that the dryness is present (that is, there is an area greater than or equal to 3*3 mm² or a circle with a radius greater than or equal to 1.7 mm under visual observation), it will be marked as NG. If the sample test result shows that the dryness is not present, it is marked as OK. There is no dryness in the appearance of the copper-free laminates of Embodiments (E1 to E8).

According to the above embodiments, articles prepared by the resin composition of the present invention (for example, prepregs, resin films, laminates or printed circuit boards) have excellent characteristics in at least one of the copper foil peel strength of the copper-containing laminate, the interlayer bonding strength of the copper-containing laminate and the percentage of thermal expansion, and therefore can be used as a high-performance laminate that meet comprehensive needs.

The above embodiments are not intended to limit the claims of the present invention.

1. A resin composition, comprising:
100 parts by weight of vinyl-containing polyphenylene ether resin;
8 parts by weight to 20 parts by weight of a compound represented by the following formula (1); and
0.5 parts by weight to 2.5 parts by weight of a compound represented by the following formula (2), 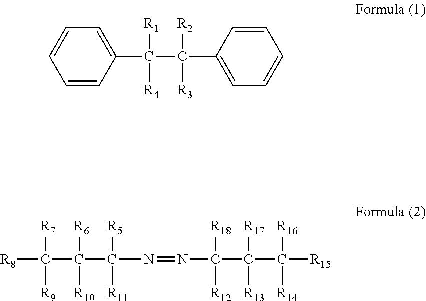
wherein each R₁, R₂, R₃ and R₄ respectively is C₁₋₄ alkyl or H, and each R₅, R₆, R₇, R₈, R₉, R₁₀, R₁₁, R₁₂, R₁₃, R₁₄, R₁₅, R₁₆, R₁₇ and R₁₈ respectively is C₁ alkyl or H.

2. The resin composition of claim 1, wherein the compound represented by the formula (1) is a compound of the following formula (1-1), (1-2) or (1-3):

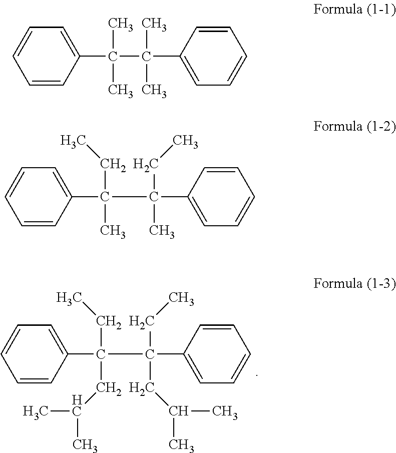

3. The resin composition of claim 1, wherein the compound represented by the formula (2) is a compound of the following formula (2-1) or (2-2):

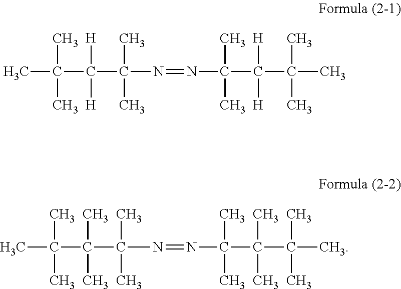

4. The resin composition of claim 1, further comprising: divinylbenzene copolymer, maleimide resin, polyolefin other than divinylbenzene copolymer, di(vinylphenyl)ethane, triallyl isocyanurate, triallyl cyanurate, divinylbenzene, diallyl isophthalate, styrene maleic anhydride copolymer resin, phenol resin, benzoxazine resin, cyanate ester resin, polysiloxane resin, polyester resin, epoxy resin, polyamide resin, polyimide resin or a combination of thereof.

5. The resin composition of claim 1, further comprising: an inorganic filler, a solvent, a siloxane compound, an inhibitor, a flame retardant, a colorant, a toughener, a core-shell rubber or a combination thereof.

6. An article manufactured using the resin composition of claim 1, wherein the article includes a prepreg, a resin film, a laminate or a printed circuit board.
